(19) United States
(12) Patent Application Publication
(10) Pub. No.: US 2025/0191996 A1
(43) Pub. Date: Jun. 12, 2025

(54) Structural Thermal Interface Pad

(71) Applicant: YUCI SHEN, LIVERMORE, CA (US)

(72) Inventor: YUCI SHEN, LIVERMORE, CA (US)

(21) Appl. No.: 18/537,665

(22) Filed: Dec. 12, 2023

(51) Int. Cl. H01L 23/42

(52) U.S. Cl. CPC H01L 23/42

(57) ABSTRACT

The disclosure describes a structural thermal interface pad between two opposing elements such as a flip chip and a heatsink of an electronic device to provide a thermal pathway for heat transfer from one to the other, comprising: a structural sheet and a filling material, wherein the structural sheet includes a first structure and a second structure, the first structure is an array of small holes, the second structure is an array of convex and/or concave bowls, and the filling material fills in a space of the structural sheet, covering at least a portion of the structural sheet. The disclosure also describes a structural thermal interface pad, comprising: a structural pillow and a filling material, wherein the structural pillow includes three layers of sheets, where the two outer sheets form an envelope, enclosing the middle sheet inside, and the middle sheet includes a first structure and a second structure.

### TECHNICAL FIELD OF THE DISCLOSURE

The disclosure relates generally to a thermal interface material (TIM), and particularly to a thermal interface pad disposed between two opposing elements such as a heat generating element like a flip chip and a heat dissipating element like a lid or heatsink of an electronic device including a flip chip package so as to transfer heat from one to the other.

### BACKGROUND OF THE DISCLOSURE

In an electronic device with a semiconductor chip being a heat-generating element, a thermal interface material (TIM) is needed to fill a gap between the semiconductor chip and a heat-dissipating element. One example is a TIM is disposed in a gap between a flip chip of a flip chip package and a cooler (like a heatsink or a cold plate) mounted over the flip chip package, and another example is a TIM is disposed in a gap between a lid of a lidded flip chip package and a cooler (like a heatsink or a cold plate) mounted over the lid of the lidded flip chip package. The different types of TIM basically include thermal pads, thermal greases, phase change materials and liquid metals. Of these types of TIM, a thermal interface pad is easiest to use. Thermal interface pads of prior arts basically include two types of structures. One is based on a thermally conductive particle filled in a matrix material, such as a silicone or resin, and the other is based on a thermally conductive porous pad filled with a resin or other glue type of material. An ideal thermal interface pad is desired to include such features as high thermal conductivity, low contact resistance, compressible/recoverable capability under pressure and long-term stability. However, thermal interface pads of prior arts are always not satisfactory in at least one or two of these mentioned features. To have such an ideal thermal interface pad with all the desired features like high thermal conductivity, low contact resistance, compressible/recoverable capability under pressure and long-term stability, a structural thermal interface pad is described in the present disclosure.

### SUMMARY OF THE DISCLOSURE

An electronic device including a structural thermal interface pad disposed between two opposing elements such as a heat generating element like a flip chip and a heat dissipating element like a lid or heatsink of an electronic device including a flip chip package is described in the present invention, wherein a structural thermal interface pad of one preferred embodiment of the present invention, comprising: a structural sheet and a filling material, wherein the structural sheet with a top surface and a bottom surface includes a first structure and a second structure, the first structure is an array of small holes completely passing through the sheet from its top surface to its bottom surface, and the second structure is an array of convex and/or concave bowls on the top surface and/or on the bottom surface of the structural sheet; and wherein the filling material fills in a space of the structural sheet, covering at least a portion of the top surface and a portion of the bottom surface of the structural sheet.

A structural thermal interface pad of another preferred embodiment of the present invention, comprising: a structural pillow and a filing material, wherein the structural pillow with a top surface and a bottom surface includes an upper sheet, a lower sheet and a middle sheet, each sheet has a top surface and a bottom surface, the upper and lower sheets form an envelope, enclosing the middle sheet inside; wherein each sheet includes an array of small holes completely passing through the sheet from its top surface to its bottom surface; the middle sheet includes a first structure and a second structure, the first structure is the array of small holes, and the second structure is an array of convex and/or concave bowls on the top surface and/or on the bottom surface of the structural sheet; and wherein the filling material fills in a space of the structural pillow, covering at least a portion of the top surface and a portion of the bottom surface of the structural pillow.

The features and advantages of the embodiments of the present invention will become more apparent from the detailed descriptions in conjunction with the drawings below. The drawings and associated descriptions are to illustrate the embodiments of the present disclosure, not to limit the scope of what is claimed.

### BRIEF DESCRIPTION OF THE DRAWINGS

FIG. 1 is a schematic diagram for illustrating a structural thermal interface pad disposed two opposing elements of an electronic device of one preferred embodiment of the present invention.

FIG. 1A is a schematic diagram for further illustrating the structural thermal interface pad as shown in FIG. 1.

FIG. 2, FIG. 2A and FIG. 2B are schematic diagrams for illustrating that the structural thermal interface pad as shown in FIG. 1 can further include some other features, like a ring-form of adhesive, glue or rubber on its bottom surface and/or a positioning rim along its peripheral edge.

FIG. 3 is a schematic diagram for illustrating a structural pillow for a structural thermal interface pad of another preferred embodiment of the present invention.

FIG. 3A is a schematic diagram for illustrating a structural thermal interface pad based on a structural pillow of another preferred embodiment of the present invention.

FIG. 4 and FIG. 4A are schematic diagrams for illustrating an electronic device including a structural thermal interface pad as shown in FIG. 3A of one preferred embodiment of the present invention.

FIG. 5 is a schematic diagram for illustrating an electronic device including a structural thermal interface pad as shown in FIG. 3A of another preferred embodiment of the present invention.

### DETAILED DESCRIPTION OF THE PREFERRED EMBODIMENT

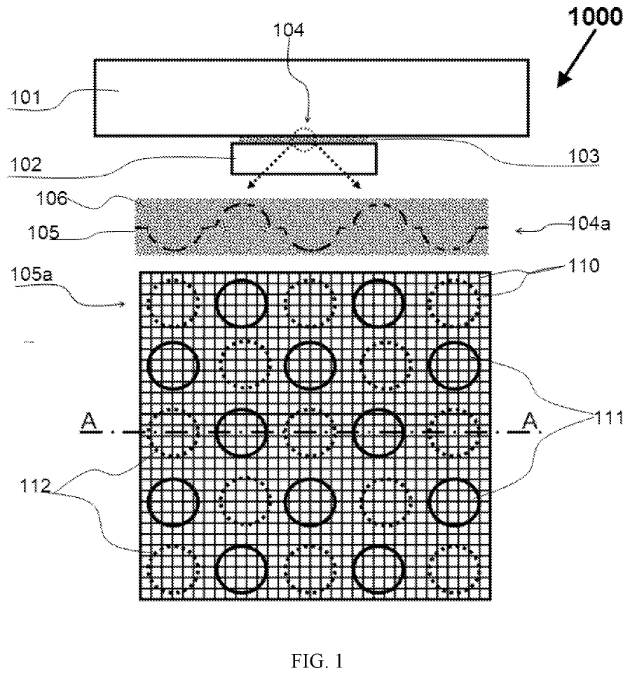

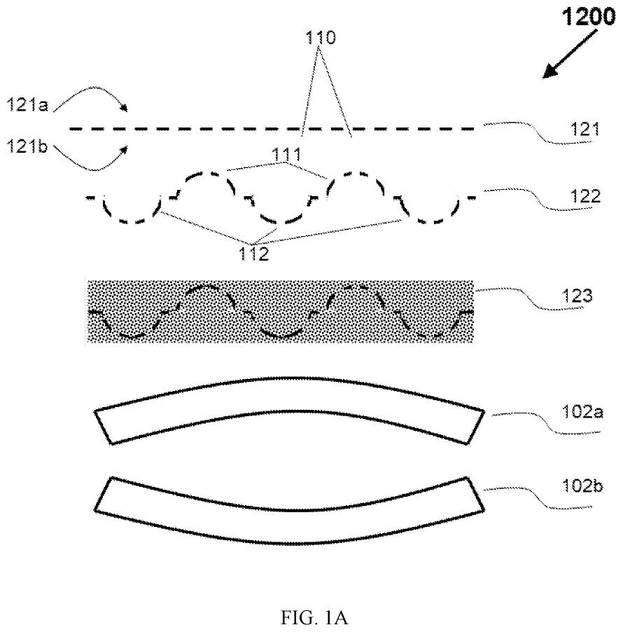

FIG. 1 is a schematic diagram for illustrating a structural thermal interface pad disposed between two opposing elements of an electronic device of one preferred embodiment of the present invention. The numerical symbol 1000 in FIG. 1 designates an electronic device, including two opposing elements 101 and 102, and a structural thermal interface pad 103, in which the structural thermal interface pad 103 is disposed between the two opposing elements 101 and 102 to provide a thermal pathway for heat transfer from one to the other. A small portion of the structural thermal interface pad 103 as illustrated in a dash circle 104 is enlarged for a detailed view as designated by 104a, in which the numerical symbols 105 and 106 respectively designate a structural sheet and a filling material. The numerical symbol 105a is for illustrating the structural sheet 105 from its top view, such that the 105 can be viewed as a cross-section along the dashed line A of the top view 105a. As illustrated by the cross-sectional and top views 105/105a of the structural sheet 103, it has a top surface and a bottom surface and includes a first structure and a second structure, wherein the first structure is an array of small holes 110 completely passing through structural sheet 103 from its top surface to its bottom surface, and the second structure is an array of convex and/or concave bowls 111 and 112 on the top surface and/or on the bottom surface of the sheet 105/105a, which can be formed by extruding the structural sheet outwards from its top surface and/or bottom surface. The filling material 106 fills in a space of the structural sheet 105, covering at least a portion of the top surface and a portion of the bottom surface of the structural sheet 105, as illustrated by the enlarged view 104a. The first structure 110 and the second structure 111/112 of the structural sheet 105 and more features of the structural thermal interface pad 103 will be further illustrated in conjunction with drawings below.

FIG. 1A is a schematic diagram for further illustrating the structural thermal interface pad as shown in FIG. 1. The numerical symbol 1200 in FIG. 1A designates some elements for illustrating a method of designing the first structure 110 and the second structure 111/112 in the structural sheet 105 as shown in FIG. 1, in which the numerical symbol 121 designates a sheet with an array of small holes 110, the 121a and 121b designate a top surface and a bottom surface of the sheet 121, the 122 designates a structural sheet having an array of convex and/or concave bowls 111/112 on its top surface 121a and/or bottom surface 121b, which can be formed by extruding the sheet 121 outwards from its top surface 121a and/or bottom surface 121b, the 123 designates a filling material which fills in a space of the structural sheet 105 as shown in FIG. 1, including the array of small holes 110 and the array of convex and/or concave bowls 111/112, and the filling material also covers at least a portion of the top surface and a portion of the bottom surface of the structural sheet 105. The 102a and 102b in FIG. 1A designate a deformation or warpage of the element 102 of the electronic device 1000 as shown in FIG. 1 due to a temperature change. When the element 102, such as a flip chip of a flip chip package or a lid of a lidded flip chip package, warps upwards or downwards due to a temperature change, the volume and thickness of the gaps among the element 102, the structural sheet 105 and the element 103 as shown in FIG. 1 will change. When this happens, the array of convex and/or concave bowls 111/112 can deform under a pressure according to the change of the volume and thickness, and the array of small holes can allow the filling material to pass from one side to the other side of the structural sheet 105. In such a way, a filling material with fluidity, like a liquid metal, can be used with the structural sheet to achieve an ideal thermal interface pad with the features like high thermal conductivity, low contact resistance, compressible/recoverable capability under pressure and long-term stability.

It is noted that a mesh, like a copper mesh or a carbon-fiber mesh can be used as a structural sheet with an array of small holes, an array of convex and/or concave bowls can be made by extruding the mesh, and various shapes of convex and/or concave bowls can be made, not limited to a circular shape as illustrated in FIG. 1 and FIG. 1A. Even though a structural thermal interface pad based on a copper mesh and a liquid metal are preferred in one embodiment of the present invention, a thermally-conductive paste or mud as a filling material can also be used together with a structural sheet based on a copper mesh or a carbon-fiber mesh according to a specific application. According to a specific application, the dimensions of the array of small holes and the array of bowls of the structure sheet can be designed, such as a preferable hole to hole pitch of about 20 μm to 50 μm and a preferable bowl to bowl pitch of about 500 μm to 1000 um for a structure thermal interface pad to transfer heat from a flip chip to other elements, like a lid or heatsink. Furthermore, the array of bowls on the top surface and/or on the bottom surface of the sheet preferably have a height of about 100 μm to 500 μm. In general, the bowl to bowl pitch is preferably much larger than the hole to hole pitch, like larger by about 5 to 50 times. It is also noted that even though a structural thermal interface pad including one layer of structural sheet is illustrated, a structural thermal interface pad including more layers of structural sheets can be similarly made when needed in a specific application.

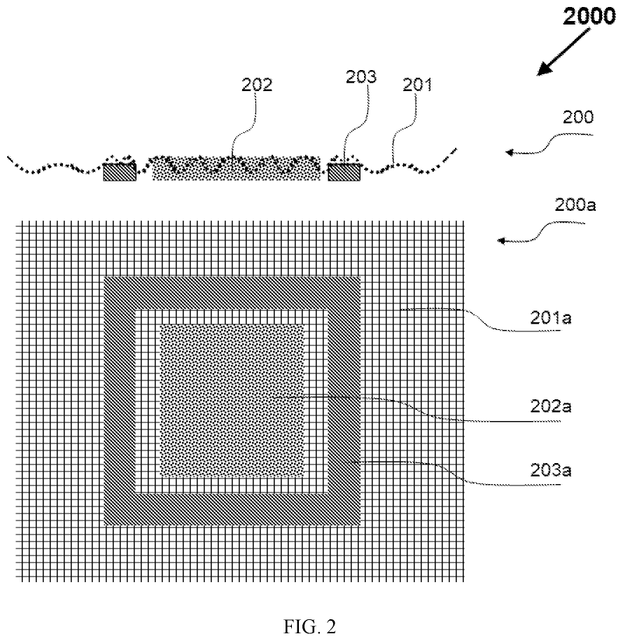

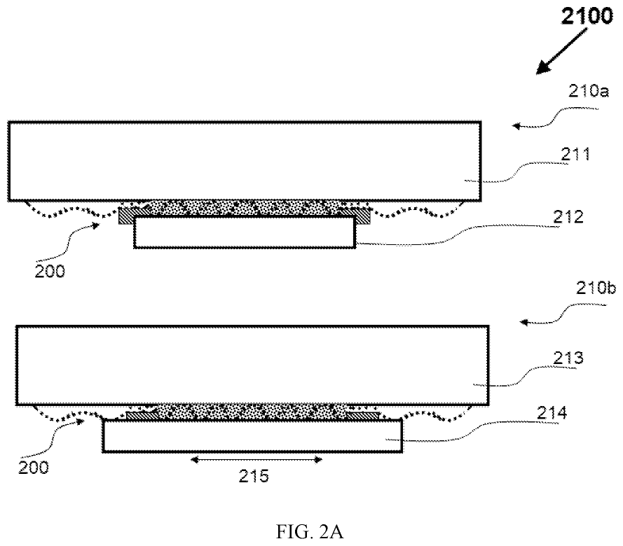

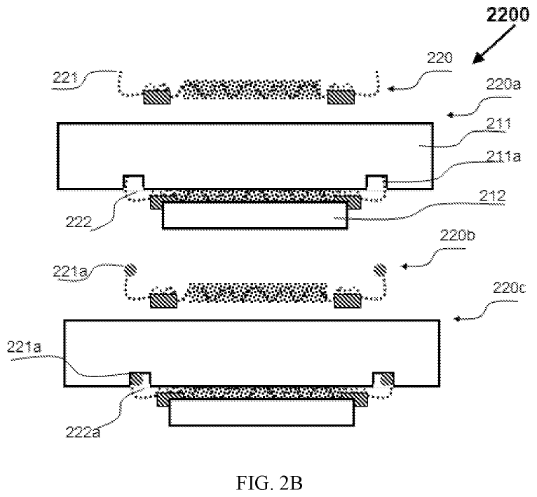

FIG. 2 and FIG. 2A are schematic diagrams for illustrating that the structural thermal interface pad as shown in FIG. 1 and FIG. 1A further includes a ring-form of adhesive, glue or rubber on its bottom surface. The numerical symbol 2000 in FIG. 2 designates a structural thermal interface pad, in which the numerical symbol 200 designates a structural thermal interface pad including a structural sheet 201, a filling material 202 and a ring-form of adhesive, glue or rubber 203 on the bottom surface of the structural sheet 201. The numerical symbol 200a designates a bottom view of the structural thermal interface pad 200 to further illustrate the ring-form of adhesive, glue or rubber 203, in which the 201a, 202a and 203a designate the 201, 202 and 203 from their bottom views, respectively. It is seen that the filling material 202 is preferably filled in a portion of the structural sheet 201 according to an area of a heat generating element of an electronic device. The numerical symbol 2100 in FIG. 2A designates that the structural thermal interface pad 200 is disposed in a gap between a heat dissipating element and a heat generating element, in which the 200a designates the structural thermal interface pad 200 is disposed in a gap between a heat dissipating element 211 and a heat generating element 212, wherein the ring-form of adhesive, glue or rubber 203 as shown in FIG. 2 is arranged along a peripheral edge of the heat generating element 212, such as a flip chip; and the numerical symbol 210b designates the structural thermal interface pad 200 is disposed in a gap between a heat dissipating element 213 and a heat generating element 214, such as a flip chip and a lid of a lidded flip chip package, wherein the ring-form of adhesive, glue or rubber 203 is arranged at an inner region inside a peripheral edge of the heat generating element 214. It is noted that the ring-form of adhesive, glue or rubber 203 as shown in FIG. 2 on the bottom surface of the structural sheet 201 is designed to avoid the filling material 202/202a as shown in FIG. 2 to flow out from the peripheral edge of the heat generating element 212 or 214. It is also noted that depending on a specific application, a ring-form of adhesive, glue or rubber 203 can be placed at and along a peripheral edge of a heat generating element as shown in the 210a or at a peripheral inner region of a heat generating element as shown in the 210b. In the two examples 210a and 210b, the heat generating element 212 preferably designates a flip chip of a flip chip package, and the heat generating element 214 preferably designates a lidded flip chip package with a flip chip in a smaller region as shown by the arrow 215.

FIG. 2B is a schematic diagram for illustrating that the structural thermal interface pad as shown in FIG. 1 or FIG. 1A further includes a positioning rim along its peripheral edge. The numerical symbol 2200 in FIG. 2B designates a structural thermal interface pad having a positioning rim and its application in an electronic device, in which the 220 designates the structural thermal interface pad further including a positioning rim 221, the 220a designates the structural thermal interface pad 220 is disposed in a gap between a heat dissipating element 211 and a heat generating element 212, wherein the heat dissipating element 211 has a notch 211a for the positioning rim 221 to be placed in, and the 222 designates a cavity formed by the positioning rim 221 and the notch 211a; and the 220b designates the structural thermal interface pad 220 further including a glue edge 221a at an edge region of the positioning rim 221, the 220c designates an application of the structural thermal interface pad 220b, in which the 222a designates a cavity formed by the positioning rim 221 with the glue edge 221a and the notch 211a. It is noted that the cavity 222 and the cavity 222a are for a safety measure in case a filling material, such as liquid metal, flows out from the gap.

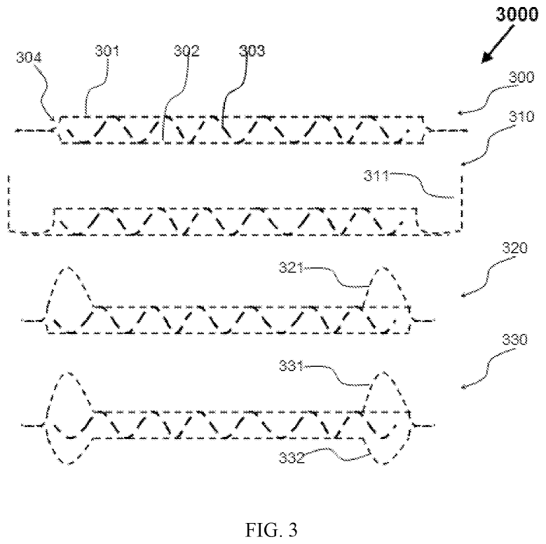

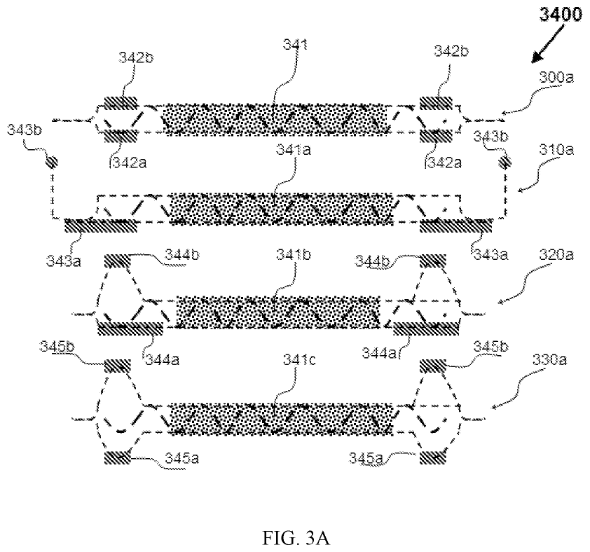

FIG. 3 and FIG. 3A are schematic diagrams for illustrating a structural thermal interface pad of another preferred embodiment of the present invention. The numerical symbol 3000 in FIG. 3 designates a structural pillow with various features, in which the numerical symbol 300 designates a structural pillow with a top surface and a bottom surface, including an upper sheet 301, a lower sheet 302 and a middle sheet 303, wherein each sheet has a top surface and a bottom surface, the upper and lower sheets 301/302 form an envelope 304 that encloses the middle sheet 303 inside, and each sheet includes an array of small holes completely passing through the sheet from its top surface to its bottom surface. The middle sheet 303 includes a first structure and a second structure, as similarly illustrated by the drawings in FIG. 1 and FIG. 1A, wherein the first structure is the array of small holes, and the second structure is an array of convex and/or concave bowls on the top surface and/or on the bottom surface of the middle sheet. The 310 designates that the structural pillow 300 further includes a positioning rim 311 along its peripheral edge; the 320 designates that the structural pillow 300 further includes a bump-form of cavity 321 along its peripheral edge, which can be used as a positioning bump; and the 330 designates that the structural pillow 300 further includes another bump-form of cavity 331/332 along its peripheral edge, which can be used as a positioning bump. It is noted that the usage of the bump-form of cavity 321 and the bump-form of cavity 331/332 will be explained in conjunction with drawings below. The numerical symbol 3400 in FIG. 3A designates a structural thermal interface pad based on the structural pillow as illustrated in FIG. 3, in which the numerical symbol 300a designates a structural thermal interface pad based on the structural pillow 300, including a filling material 341, and preferably further including a ring-form of adhesive, glue or rubber 342a and/or 342b on its bottom and/or top surfaces respectively. The numerical symbol 310a designates a structural thermal interface pad based on the structural pillow 310, including a filling material 341a, and preferably further including a ring-form of adhesive, glue or rubber 343a on its bottom surfaces and/or a ring-form of adhesive or glue edge 343b at an edge region of the positioning rim 311; the numerical symbol 320a designates a structural thermal interface pad based on the structural pillow 320, including a filling material 341b, and preferably further including a ring-form of adhesive, glue or rubber 344a on its bottom surface and/or a ring-form of adhesive, glue or rubber 344b at a top region of the bump-form of cavity 321; and the numerical symbol 330a designates a structural thermal interface pad based on the structural pillow 330, including a filling material 341c, and preferably further including a ring-form of adhesive, glue or rubber 345a at a bottom region of the bump-form of cavity 332 and/or a ring-form of adhesive, glue or rubber 345b at a top region of the bump-form of cavity 331.

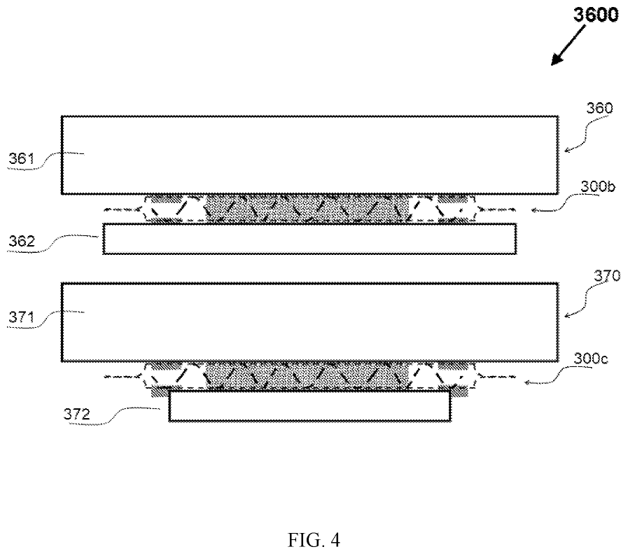

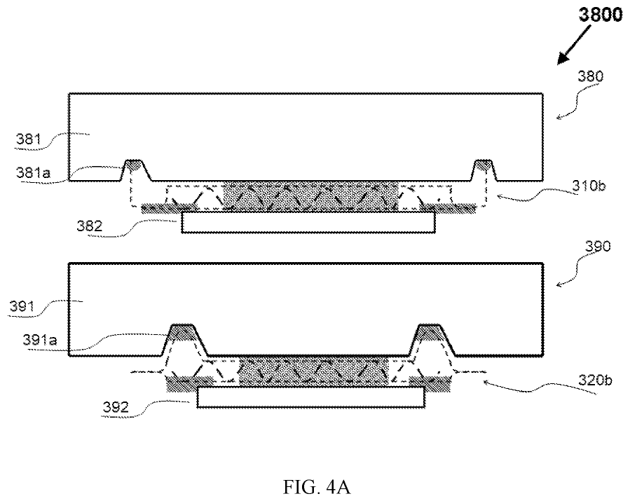

FIG. 4 and FIG. 4A are schematic diagrams for illustrating an electronic device based on the structural thermal interface pad as shown in FIG. 3A, which is disposed in a gap between two opposing elements, such as a heat generating element and a heat dissipating element of the electronic device of one preferred embodiment of the present invention. The numerical symbol 3600 in FIG. 4 is for illustrating two examples of an electronic device having the structural thermal interface pad 300a as shown in FIG. 3A, in which the numerical symbol 360 designates an electronic device including a structural thermal interface pad 300b (or the 300a in FIG. 3A) disposed in a gap between a heat generating element 362 and a heat dissipating element 361 of the electronic device; and the numerical symbol 370 designates an electronic device including a structural thermal interface pad 300c (or the 300a in FIG. 3A) disposed in a gap between a heat generating element 372 and a heat dissipating element 371 of the electronic device. The numerical symbol 3800 in FIG. 4A is for illustrating another two examples of an electronic device having the structural thermal interface pad 310a and 320a as shown in FIG. 3A, in which the numerical symbol 380 designates an electronic device including a structural thermal interface pad 310b (or the 310a in FIG. 3A) disposed in a gap between a heat generating element 382 and a heat dissipating element 381 with a notch 381a of the electronic device; and the numerical symbol 390 designates an electronic device including a structural thermal interface pad 320b (or the 320a in FIG. 3A) disposed in a gap between a heat generating element 392 and a heat dissipating element 391 with a notch 391a of the electronic device.

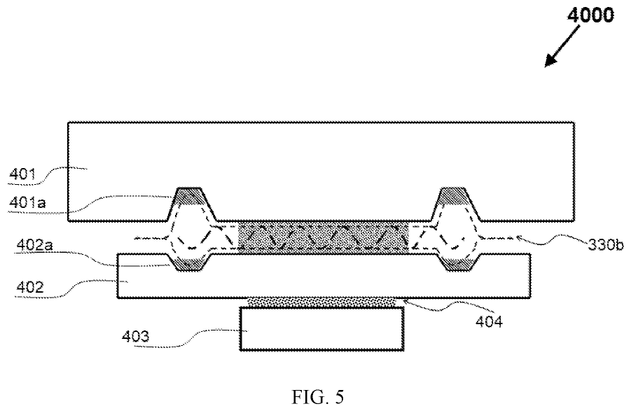

FIG. 5 is a schematic diagram for illustrating an electronic device based on the structural thermal interface pad 330a as shown in FIG. 3A, which is disposed in a gap between a heat generating element and a heat dissipating element of the electronic device of another preferred embodiment of the present invention. The numerical symbol 4000 in FIG. 5 is for illustrating an example of an electronic device with the structural thermal interface pad 330a as shown in FIG. 3A, in which a structural thermal interface pad 330b (or the 330a in FIG. 3A) is disposed in a gap between a heat generating element 402 and a heat dissipating element 401; the 402 and the 401 have a pair of notches 402a and 401a for the bump-form of cavity 332/331 with the ring-form of adhesive, glue or rubber 345a/345b as shown in FIG. 3A to be placed in. It is noted that the electronic device in the example is for a lidded flip chip package, where the 402 is for illustrating a lid, the 403 for a flip chip and the 404 for another TIM between the lid 402 and the flip chip 403 of the lidded flip chip package. It is seen that a heat transfer pathway for the electronic device shown in FIG. 5 is from the flip chip 403 to the lid 402 via 404 and then to the heat dissipating element 401 via 330b. So, the structural thermal interface pad can be disposed in any two opposing elements of an electronic device for an efficient hear transfer between them in the scope of the present invention.

The spirit and scope of the present invention is to use a sheet structure with a first structure and a second structure to form a structural thermal interface pad to achieve an ideal thermal interface pad, wherein the first structure is for a filling material to pass from one side to the other of the structure sheet, and the second structure can work as a compressible/recoverable element so as to match a deformation or warpage of a heat generating element and/or a heat dissipating element of an electronic device. According to the spirit and scope of the present invention, various structural thermal interface pads by adding some other features can be flexibly designed.

Although the present invention is described in some details for illustrative purpose with reference to the specific embodiments and drawings, it is apparent that many other modifications and variations may be made without departing from the spirit and scope of the present invention.

What is claimed is:

1. An electronic device including a structural thermal interface pad disposed between two opposing elements of the electronic device, said structural thermal interface pad, comprising:
A structural sheet and a filling material;
wherein the structural sheet with a top surface and a bottom surface includes a first structure and a second structure, the first structure is an array of small holes completely passing through the structural sheet from its top surface to its bottom surface, and the second structure is an array of convex and/or concave bowls on the top surface and/or on the bottom surface of the structural sheet; and
wherein the filling material fills in a space of the structural sheet, covering at least a portion of the top surface and a portion of the bottom surface of the structural sheet.

2. The electronic device of claim 1, wherein the structural sheet with an array of small holes is a thermally-conductive mesh, including a copper mesh or a carbon-fiber mesh.

3. The electronic device of claim 1, wherein the structural sheet further includes a positioning rim along its peripheral edge.

4. The electronic device of claim 1, wherein the structural sheet further includes a ring-form of adhesive, glue or rubber on its bottom surface.

5. The electronic device of claim 1, wherein the structural sheet further includes a positioning rim along its peripheral edge and a ring-form of adhesive, glue or rubber on its bottom surface.

6. The electronic device of claim 1, wherein the two opposing elements are a flip chip and a lid of a lidded flip chip package.

7. The electronic device of claim 1, wherein the two opposing elements are a flip chip of a flip chip package and a heatsink or a lid of a lidded flip chip package and a heatsink.

8. The electronic device of claim 1, wherein the filling material is a liquid metal, including gallium and gallium alloys.

9. The electronic device of claim 1, wherein the filling material is a thermally-conductive paste or mud.

10. An electronic device including a structural thermal interface pad disposed between two opposing elements of the electronic device, said structural thermal interface pad, comprising:
A structural pillow and a filing material;
wherein the structural pillow with a top surface and a bottom surface includes an upper sheet, a lower sheet and a middle sheet, each sheet has a top surface and a bottom surface, the upper and lower sheets form an envelop, enclosing the middle sheet inside;
wherein each sheet includes an array of small holes completely passing through the sheet from its top surface to its bottom surface; the middle sheet includes a first structure and a second structure, the first structure is an array of small holes, and the second structure is an array of convex and/or concave bowls on the top surface and/or on the bottom surface of the structural sheet; and
wherein the filling material fills in a space of the structural pillow, covering at least a portion of the top surface and a portion of the bottom surface of the structural pillow.

11. The electronic device of claim 10, wherein each sheet with an array of small holes is a thermally-conductive mesh, including a copper mesh or a carbon-fiber mesh.

12. The electronic device of claim 10, wherein the structural pillow further includes a positioning rim along its peripheral edge.

13. The electronic device of claim 10, wherein the structural pillow further includes a ring-form of cavity along its peripheral edge.

14. The electronic device of claim 13, wherein the structural pillow further includes a ring-form of adhesive, glue or rubber at and along the ring-form of cavity.

15. The electronic device of claim 10, wherein the lower sheet further includes a ring-form of adhesive, glue or rubber on its bottom surface and/or the upper sheet further includes a ring-form of adhesive, glue or rubber on its top surface.

16. The electronic device of claim 10, wherein the two opposing elements are a flip chip and a lid of a lidded flip chip package.

17. The electronic device of claim 1, wherein the two opposing elements are a flip chip of a flip chip package and a heatsink or a lid of a lidded flip chip package and a heatsink.

18. The electronic device of claim 10, wherein one or both of the upper and lower sheets further include an array of convex and/or concave bowls on their top and/or bottom surfaces.

19. The electronic device of claim 10, wherein the filling material is a liquid metal, including gallium and gallium alloys.

20. The electronic device of claim 10, wherein the filling material is a thermally-conductive paste or mud.
